(19) United States
(12) Patent Application Publication
(10) Pub. No.: US 2016/0315059 A1
(43) Pub. Date: Oct. 27, 2016

(54) METHOD OF PRODUCING BUMPS IN ELECTRONIC COMPONENTS, CORRESPONDING COMPONENT AND COMPUTER PROGRAM PRODUCT

(71) Applicant: STMICROELECTRONICS S.R.L., Agrate Brianza (IT)

(72) Inventors: Paolo CREMA, Vimercate (IT); Pierangelo MAGNI, Villasanta (IT)

(21) Appl. No.: 14/980,616

(22) Filed: Dec. 28, 2015

(30) Foreign Application Priority Data
Apr. 24, 2015 (IT) TO2015A000229

(51) Int. Cl. H01L 23/00; B29C 67/00; G05B 19/418

(52) U.S. Cl. CPC H01L 24/13; H01L 24/11; G05B 19/418; B29C 67/0088; H01L 2224/1183; H01L 2224/1143; H01L 2224/13019; H01L 2224/13017; H01L 2224/13015; H01L 2224/13023; H01L 2224/13111; H01L 2224/13147; H01L 2224/13155; G05B 2219/35134; G05B 2219/49007; B33Y 50/02

(57) ABSTRACT

An electronic component, such as an integrated circuit, includes one or more circuits with bumps extending in a longitudinal direction outward from the circuit. The bumps may be formed, e.g., by 3D printing, with at least one protrusion extending away from the longitudinal direction.

### TECHNICAL FIELD

This description relates to electronic components, and more particularly, to producing “bumps” in electronic components such as e.g., integrated circuits (ICs).

### BACKGROUND

So-called bumps may be used to provide an electrical and/or a mechanical connection to a package and/or a board in electronic components, such as integrated circuits (ICs). Thermal bumps are also known for use in electronics and optoelectronic packaging to add thermal management functionality on the surface of a chip or to another electrical component. Bumps/pillars may be produced with a variety of processes.

For instance, solder bumps may be produced by depositing material (e.g., solder paste or solder balls) and pillar bumps may be produced by electrolytic growth.

Processes such as e.g., electroplating or electroless (E-less) processes may involve masking and electrolytic growth. These may exhibit an intrinsic limitation to “vertical” pillars, that is bumps extending in a longitudinal, generally rectilinear direction.

A geometrically directed growth is generally not feasible, so that relaxing a bump pitch inevitably involves a redistribution action e.g., via plural lithographic steps and electroplating or E-less steps.

Pillar bumps may include a solder layer at their tip for soldering to a board. During thermal testing of wafers the solder layer may soften and be damaged by probes. Damage may include the formation of cavities. Air may be trapped in those cavities contacting the board which may adversely affect the useful life of the component.

### SUMMARY

One or more embodiments may refer to a corresponding component (e.g., a microelectronic component such as an integrated circuit).

Also, one or more embodiments may refer to a computer program product loadable into the memory of at least one computer configured to drive a 3D printing apparatus and include software code portions for executing the 3D printing steps of the method of one or more embodiments when the product is run on at least one computer. As used herein, reference to such a computer program product is understood as being equivalent to reference to a computer-readable medium containing instructions for controlling a 3D printing apparatus in order to coordinate implementation of the method according to one or more embodiments. Reference to “at least one computer” is intended to highlight the possibility for one or more embodiments to be implemented in modular and/or distributed form.

One or more embodiments may rely on the recognition that 3D printing (additive manufacturing or AM) is becoming a common technology, with dimensions, resolution, and pitch becoming increasingly accurate and with small sizes.

One or more embodiments make it possible to form in a single step (e.g., metal) bumps/pillars including one or more “lateral” structures which protrude sidewise relative to the longitudinal direction of the bump, and which may be used e.g., to carry signals from two sides of a chip to a wider area.

In one or more embodiments, the lateral protruding structure may be produced as one-piece with the bump body, that is as a single piece of material, exempt from any joints (e.g., soldering) thus dispensing with any (ohmic) resistances possibly associated with such joints.

### BRIEF DESCRIPTION OF THE DRAWINGS

One or more embodiments will now be described, purely by way of non-limiting example, with reference to the annexed figures, wherein:

FIG. 1 is a schematic representation of an electronic component of the prior art;

FIG. 2 is a schematic representation of a process which may be used in one or more embodiments; and

FIG. 3 is a schematic representation of a T-shaped protrusion achievable in one or more embodiments;

FIG. 4 is a schematic representation of a V-shaped protrusion achievable in one or more embodiments; and

FIG. 5 is a schematic representation of a cantilever protrusion achievable in one or more embodiments.

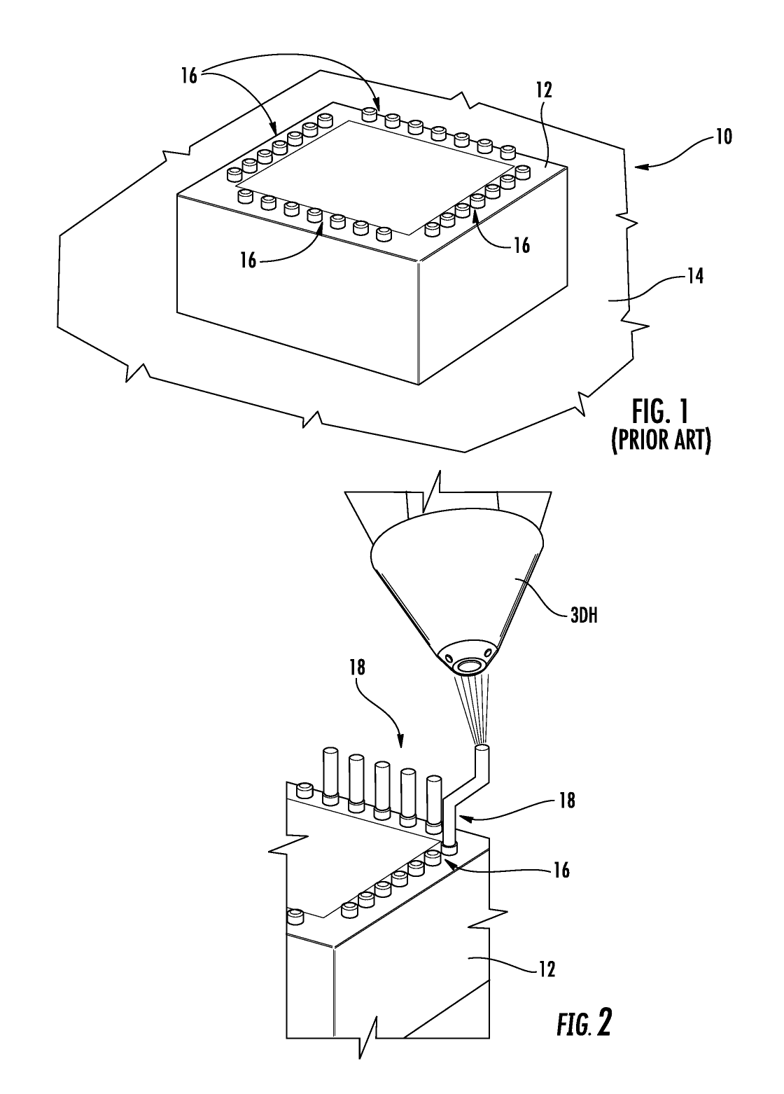

It will be appreciated that, in order to facilitate understanding the embodiments, the various figures may not be drawn to a same scale.

### DETAILED DESCRIPTION

In the ensuing description, one or more specific details are illustrated, aimed at providing an in-depth understanding of examples of embodiments. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment. Moreover, particular formations, structures, or characteristics may be combined in any adequate way in one or more embodiments. That is, one or more characteristics exemplifies in connection with a certain figure can be applied to any embodiment as exemplified in any other figure.

The references used herein are provided for convenience and hence do not define the scope of protection or the scope of the embodiments.

Throughout the figures, embodiments of an electronic component are generally indicated as 10. Such embodiments may include an electronic circuit 12 such as a chip (or “die”), which may be arranged on a support substrate 14. In one or more embodiments, the substrate 14 may be a circuit board such as e.g. a Printed Circuit Board (PCB). In one or more embodiments, the substrate may be a die pad. In one or more embodiments a die pad may not be provided. In one or more embodiments the die 12 may be arranged within a package or located at the (e.g., bottom) surface of the package.

Whatever the details of the embodiments, the electronic circuit 12 may include die bond pads 16 which may provide an electrical connection of the circuit to the package and/or the board.

So-called bumps (sometimes referred to as “pillars”) 18 may be provided (e.g., grown on the pads 16) to provide an electrical path and/or a mechanical connection to the package and/or the board.

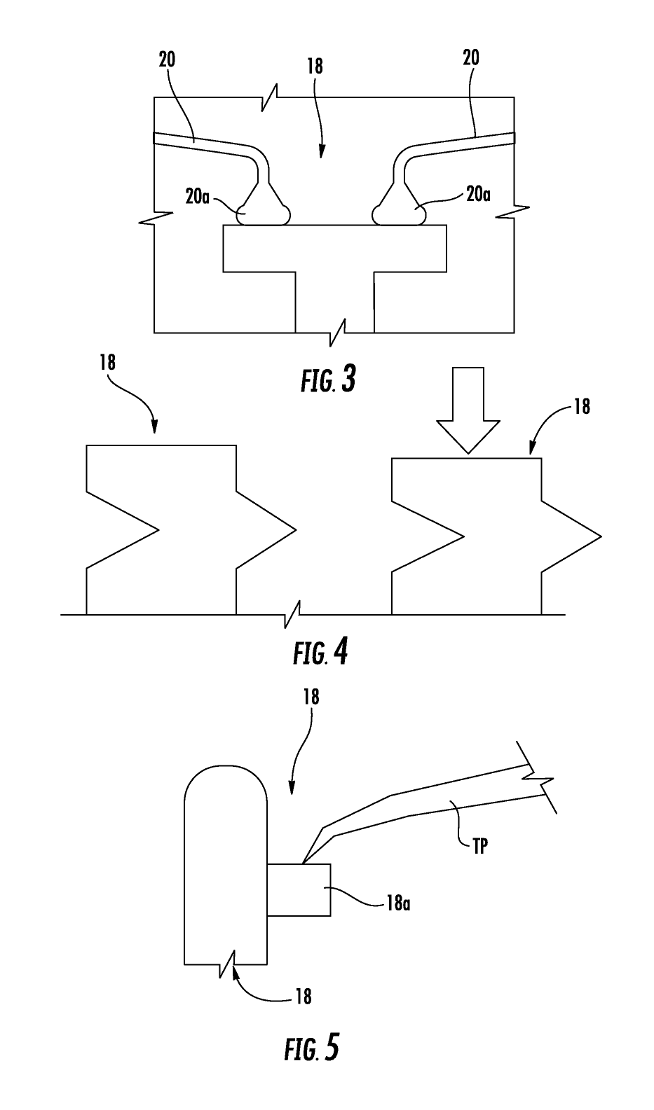

Wiring 20 exemplary of such electrical paths (e.g., to a lead frame including package pins—not visible in the Figure) soldered at one or more electrical connection locations 20a to a bump 18 is shown in FIG. 3. A spring-like bump 18 adapted to provide a stress-dampening mechanical coupling to e.g., a package or board (not visible in the Figure) is shown in FIG. 4 as further discussed below. A bump 18 having a cantilever-like protrusion 18a adapted to be contacted by a test probe TP is shown in FIG. 5 as further discussed in the following.

The bumps 18 in FIGS. 3 through 5 are thus generally exemplary of one or more embodiments including at least one bump 18 extending in a longitudinal direction of the bump 18, the bump 18 being produced, possibly as a single piece of material (e.g., with no joints), with at least one protrusion (e.g., the sides of the enlarged head of the mushroom-shaped or T-shaped bump 18 of FIG. 3, the intermediate V-shaped portion of the bump 18 of FIG. 4, or the cantilever-like protrusion 18a of the bump 18 of FIG. 5) extending away of the longitudinal direction of the bump 18.

The designation 3D printing (or additive manufacturing, AM) covers various processes which may be used to produce three-dimensional objects by way of an additive process. In such a process, layers of material may be subsequently laid by way of a “3D printer” which may be regarded as a sort of industrial robot.

A 3D printing process may be computer controlled so that an object with a certain shape/geometry may be produced starting e.g., from a data source, that is by way of a computer program product for driving 3D printing apparatus and including software code portions for executing the steps of a 3D printing method when the product is run on such a computer.

The term 3D printing was originally used to designate those processes involving sequential deposition of material e.g., onto a powder bed by way of a printer head essentially resembling an ink-jet printer. The term 3D printing is generally now currently used to designate a variety of processes including e.g., extrusion or sintering processes. While the term additive manufacturing (AM) may in fact be used in this broader sense, the two designations, 3D printing and additive manufacturing (AM) will be used herein as essentially synonymous.

As used herein, wording such as e.g., “3D printing” and “3D-printed” will therefore designate an additive manufacturing process and an item produced by additive manufacturing.

In one or more embodiments, 3D printing technology may be based on the repeated deposition of microlayers of metal powders that are locally melted or fused, so that metal structures may be grown.

One or more embodiments may rely on the recognition that, while regarded as an intrinsically “slow” process, recent developments of 3D printing/AM may exhibit—in connection with materials such as copper (Cu), nickel (Ni) tin (Sn), various metal alloys—parameters which are compatible with producing bumps/pillars of electronic components such as ICs e.g. by micro-fusing metallic powders by means of a laser beam.

FIG. 2 is schematically exemplary of the possibility of using a e.g., computer-controlled laser/powder jet 3D printing head 3DH to grow metal structures (Cu, Ni, Sn and so on) of bumps/pillars 18.

Differently from conventional bumps/pillars, which may be purely linear e.g., vertical pillars, the bumps of one or more embodiments may include more complex shapes such as curves, bifurcations, zig-zag patterns and so on, that is metal bumps which may be produced, e.g., as a single piece of material (e.g., with no joints), with at least one protrusion extending away of the longitudinal direction of the bump 18.

These bump structures may extend the interconnection capability of a circuit (e.g., a chip) 12 to the surrounding environment such as a package or a printed circuit board (PCB).

For instance, in one or more embodiments, the growth of the metal bumps 18 may start from the bond pads 16 (e.g., Al) by forming a joint between the base metal of the pad and the fused metal powders grown thereon via the 3D printing process.

In one or more embodiments, the extent and direction of growth may be selected as a function of the desired layout to be obtained.

In one or more embodiments, the final connection may take place e.g., by melting or welding, possibly after turning (flipping) and placing the chip 12 on the substrate 14.

One or more embodiments may thus involve producing a set of electrically conductive (e.g., metal) bumps for an electronic component 10 e.g., by 3D printing (additive manufacturing).

Producing the bumps 18 by 3D printing paves the way to a variety of possible new applications.

For instance, fusing metal powders by a laser beam in 3D printing makes it possible to grow metal bumps on semiconductor wafers.

In one or more embodiments, bumps or pillars may be grown with a geometry including complex shapes, e.g., nonlinear shapes, including e.g., changes of direction, possibly as a single piece of material with at least one protrusion extending away of the longitudinal direction of the bump 18.

One or more embodiments may greatly facilitate e.g., relaxing too close of a bump pitch by redistributing the associated layout of a wider area.

FIGS. 3 to 5 are schematic exemplary representations of one or more embodiments.

For instance, FIG. 3 is exemplary of a mushroom-shaped or T-shaped bump 18 with an enlarged head portion extending sidewise, e.g., in both directions, away from the “stem” portion of the mushroom or T shape, that is away of the longitudinal direction (vertical in the figure) of the bump 18 thus forming plural locations 20a for connecting electrical wiring 20.

FIG. 4 is exemplary of the possibility of producing a spring-like, e.g., leaf-spring shaped, bump 18 adapted to provide a stress-dampening mechanical coupling to e.g., a package or board (not visible in the Figure). Such an arrangement may be effective in reducing stress on semiconductor (e.g., silicon) structures during assembly of the circuit. This is again exemplary of a bump 18 including an (intermediate) resilient e.g., V-shaped portion, which at least marginally protrudes away of the longitudinal direction (again vertical in the figure) of the bump 18.

FIG. 5 is exemplary of the possibility of producing a bump 18 having a lateral, cantilever-like protrusion 18a extending away from the longitudinal direction of the bump 18 (once more vertical in the figure) to be contacted by a testing probe TP thus avoiding contact (an possible damage) of the top (cap) portion of the bump 18, to be possibly soldered. In fact, in a “cactus-like” structure as exemplified in FIG. 5, a solder layer (e.g., tin) provided at the tip of the bump 18 may be left untouched by the probe TP while the lateral protrusion 18a may exhibit a smooth surface of a hard material such as e.g., copper.

An embodiment as exemplified in FIG. 5 may be advantageous over conventional testing arrangements including “twin” pads, that is pairs of adjacent pads (one to provide electrical connection, the other for testing purposes) at the chip surface, thus limiting the possibility of integrating chip circuitry under the pads.

Without prejudice to the underlying principles, the details and embodiments may vary, even significantly, with respect to what is illustrated herein purely by way of non-limiting example, without thereby departing from the extent of protection.

The extent of protection is determined by the claims that follow.

1-10. (canceled)

11. A method of producing an electronic component comprising a circuit with at least one bump extending in a longitudinal direction outward from the circuit, the method comprising:
forming the at least one bump with at least one protrusion extending away from the longitudinal direction.

12. The method of claim 11, wherein the at least one bump is formed as one piece.

13. The method of claim 11, wherein the at least one protrusion has a T-shape with an enlarged head protruding sidewise of the longitudinal direction to provide a plurality of coupling locations.

14. The method of claim 11, wherein the at least one protrusion has a mushroom-like shape with an enlarged head protruding sidewise of the longitudinal direction to provide a plurality of coupling locations.

15. The method of claim 11, wherein the at least one protrusion has a non-linear shape.

16. The method of claim 11, wherein the at least one protrusion has a curved shape.

17. The method of claim 11, wherein the at least one protrusion has a V-shape.

18. The method of claim 11, wherein the at least one protrusion is resilient.

19. The method of claim 11, wherein the at least one protrusion comprises a cantilevered protrusion.

20. The method of claim 11, wherein the at least one bump is formed by 3D printing.

21. The method of claim 11, wherein the circuit comprises at least one electrically conductive circuit pad on which the at least one bump is formed.

22. The method of claim 20, wherein the at least one bump comprises at least one of copper, nickel and tin.

23. An electronic component comprising:
a circuit;
at least one bump extending in a longitudinal direction outward from the circuit; and
at least one protrusion formed on the at least one bump, the at least one protrusion extending away from the longitudinal direction.

24. The electronic component of claim 23, wherein the electronic component comprises an integrated circuit.

25. The electronic component of claim 23, wherein the at least one bump is formed as one piece.

26. The electronic component of claim 23, wherein the at least one protrusion has a T-shape with an enlarged head protruding sidewise of the longitudinal direction to provide a plurality of coupling locations.

27. The electronic component of claim 23, wherein the at least one protrusion has a mushroom-like shape with an enlarged head protruding sidewise of the longitudinal direction to provide a plurality of coupling locations.

28. The electronic component of claim 23, wherein the at least one protrusion has a non-linear shape.

29. The electronic component of claim 23, wherein the at least one protrusion has a curved shape.

30. The electronic component of claim 23, wherein the at least one protrusion has a V-shape.

31. The electronic component of claim 23, wherein the at least one protrusion is resilient.

32. The electronic component of claim 23, wherein the at least one protrusion comprises a cantilevered protrusion.

33. The electronic component of claim 23, wherein the at least one bump is formed by 3D printing.

34. The electronic component of claim 23, wherein the circuit comprises at least one electrically conductive circuit pad on which the at least one bump is formed.

35. The electronic component of claim 33, wherein the at least one bump comprises at least one of copper, nickel and tin.

36. A non-transitory computer-readable medium storing instructions that, when executed, cause an apparatus coupled to a computing device to perform steps comprising:
forming at least one bump in a longitudinal direction outward from a circuit with at least one protrusion extending away from the longitudinal direction.

37. The non-transitory computer-readable medium of claim 36, wherein the at least one bump is formed as one piece.

38. The non-transitory computer-readable medium of claim 36, wherein the apparatus is a 3D printer.
